(19) United States
(12) Patent Application Publication
(10) Pub. No.: US 2013/0050957 A1
(43) Pub. Date: Feb. 28, 2013

(54) ELECTRONIC COMPONENT INCORPORATING BOARD AND COMPOSITE MODULE

(71) Applicant: Murata Manufacturing Co., Ltd., Nagaokakyo-shi (JP)

(72) Inventors: Nobuaki OGAWA, Nagaokakyo-shi (JP); Norio SAKAI, Nagaokakyo-shi (JP)

(73) Assignee: MURATA MANUFACTURING CO., LTD., Nagaokakyo-shi (JP)

(21) Appl. No.: 13/660,326

(22) Filed: Oct. 25, 2012

Related U.S. Application Data
(63) Continuation of application No. PCT/JP2011/055203, filed on Mar. 7, 2011.

(30) Foreign Application Priority Data
Apr. 27, 2010 (JP) 2010-102314

(51) Int. Cl. H05K 1/18; H05K 7/06

(52) U.S. Cl. 361/728; 174/258

(57) ABSTRACT

An electronic component incorporating board that is less susceptible to a solder flash phenomenon therein even with application of heat, for example, when it is mounted to another substrate, includes a core substrate, electrodes located respectively on one principal surface and the other principal surface of the core substrate, an electronic component mounted to the electrodes that are located on the one principal surface of the core substrate, and a resin layer located on the one principal surface of the core substrate and covering the electronic component, wherein surfaces of the electrodes located on the one principal surface of the core substrate are not plated.

### BACKGROUND OF THE INVENTION

1. Field of the Invention

The present invention relates to an electronic component incorporating board, and more particularly, to an electronic component incorporating board that is less susceptible to a solder flash phenomenon even with application of heat when it is mounted to another substrate. Further, the present invention relates to a composite module that is constituted by mounting one or more additional electronic components to the electronic component incorporating board of the present invention.

2. Description of the Related Art

A conventional composite module in which one or more additional electronic components are mounted to an electronic component incorporating board, as disclosed in Japanese Unexamined Patent Application Publication No. 2005-235808, has been used as a composite module constituting a highly-functional electronic circuit.

FIG. 5 is a sectional view of a composite module 500 disclosed in Japanese Unexamined Patent Application Publication No. 2005-235808.

The composite module 500 includes a core substrate 101. The core substrate 101 is, e.g., a ceramic multilayered substrate or a resin multilayered substrate. Wiring patterns 102 and via holes 103 are formed inside the core substrate 101 to constitute the desired wiring within the core substrate. Further, electrodes 104 are formed on one principal surface (on the lower side in FIG. 5) of the core substrate 101, and electrodes 105 are formed on the other principal surface (on the upper side in FIG. 5). For example, Ag or Cu is used for the wiring patterns 102, the via holes 103, and the electrodes 104 and 105.

Although not specifically described in Japanese Unexamined Patent Application Publication No. 2005-235808, platings 104a and 105a are often coated on respective surfaces of the electrodes 104 and 105 to improve solder wetting. This structure is supposed to improve the solder wetting, thereby spreading a solder with good wetting when the electronic component is mounted, and to increase strength of bonding between the electrodes 104, 105 and terminals of the electronic components. Those platings are made of, e.g., Ni/Au or Ni/Sn.

Chip-type electronic components 106, such as a capacitor, a resistor, and a coil, each having a pair of terminals 106a and 106a formed at both ends thereof, and an electronic component 107, such as an IC or a SAW device, having a plurality of terminals 107a formed on a bottom surface thereof are mounted to the electrodes 104 and 105 using solders 108. The solders 108 are supplied as cream solders onto the electrodes 104 and 105, or as solder balls onto the terminals 107a of the electronic component 107, and are then subjected to reflow in soldering. It is to be noted that the electronic components 106 and 107 mounted as described above in FIG. 5 are illustrated by way of example, and that electronic components of various types, structures and numbers may be mounted without being limited to the illustrated ones.

Further, a resin layer 109 is formed on the principal surface of the core substrate 101 on the side where the electrodes 104 are formed (i.e., on the lower principal surface in FIG. 5) such that the resin layer 109 covers the electronic components 106. The resin layer 109 is made of, e.g., a thermosetting epoxy resin, silicone resin, or cyanate resin, each containing an inorganic filler. Via holes 110 connected to the electrodes 104 of the core substrate 101 are formed inside the resin layer 109, and electrodes 111 connected to the via holes 110 are formed on a surface of the resin layer 109. For example, Ag or Cu is also used for the via holes 110 and the electrodes 111.

The electrodes 111 are used when the composite module 500 is mounted to another substrate, and platings 111a are often coated on surfaces of the electrodes 111 as well. This structure also intends to improve the solder wetting, thereby spreading a solder with good wetting when the composite module 500 is mounted, and to increase strength of bonding between the composite module 500 and the other substrate. Those platings are also made of, e.g., Ni/Au or Ni/Sn. In some cases, another thin resin layer is further formed in a portion of the surface of the resin layer 109 where the electrodes 111 are not formed.

In the related-art composite module 500 described above, however, there has been a possibility that the solder flash phenomenon may occur in the resin layer 109 with application of heat from the solders under reflow when the electronic components 106 and 107 are mounted to the other principal surface (i.e., the upper principal surface in FIG. 5) of the core substrate 101, or when the completed composite module 500 is mounted to another substrate. The causes of the solder flash phenomenon will be explained below.

In the composite module 500, as illustrated in FIG. 5, the electrodes 104 including the platings 104a coated on their surfaces are formed on the one principal surface (i.e., the lower principal surface in the drawing) of the core substrate 101, and the terminals 106a of the electronic components 106 are bonded to the electrodes 104 using the solders 108. Thereafter, the resin layer 109 is formed so as to cover the electronic components 106. In addition, resin of the resin layer 109 is also filled between the core substrate 101 and each of the electronic components 106.

In a space formed between the core substrate 101 and the electronic component 106, however, the resin may be not completely filled in the space while leaving gaps therein, or the resin may be peeled off later even though the resin has been completely filled in the space.

FIGS. 6A and 6B illustrate the composite module 500 in which gaps 112 are produced in the resin layer 109 between the core substrate 101 and the electronic component 106. It is to be noted that FIG. 6A is a sectional view, and FIG. 6B is a sectional view taken along a broken line X-X in FIG. 6A. FIG. 5 and FIG. 6A are reversed in the up-and-down direction.

The cause of producing the gaps 112 is thought to reside in the fact that the spacing between the core substrate 101 and the electronic component 106 is small. In more detail, the resin layer 109 is formed, for example, by placing a thermosetting resin sheet, which has been heated into a semi-molten state, on the core substrate 101, and by causing the resin sheet to reach and contact with the periphery of the electronic component 106. However, because the spacing between the core substrate 101 and the electronic component 106 is small, the resin forming the resin layer 109 cannot sufficiently enter between the core substrate 101 and the electronic component 106, and the gaps 112 that are not filled with the resin are produced, for example, right under the electronic component 106.

On the other hand, two causes are considered regarding a phenomenon that the resin of the resin layer 109 filled between the core substrate 101 and the electronic component 106 peels off later.

One of the causes of the peeling-off is that the strength of bonding between the core substrate 101 and the resin layer 109 is small. In more detail, as illustrated in FIG. 5, the electrodes 104 are formed on the one principal surface (i.e., the lower principal surface in the drawing) of the core substrate 101 for mounting of the electronic components 106 or for functioning as the wiring pattern. Further, the resin layer 109 is bonded to the electrodes 104 on surfaces of which the platings 104a are coated. However, each electrode 104 having the plating 104a coated thereon exhibits smaller strength of the bonding with respect to the resin than an electrode not plated. More specifically, the surface of the electrode formed by baking a conductive paste, for example, includes pores that are produced by flying-away of portions of the resin in the conductive paste, and has large surface roughness, thus providing an anchor function with respect to the resin that is bonded to the electrode surface. However, because the pores are filled with the plating coated on the electrode surface, the surface roughness is reduced and the anchor function is deteriorated.

Further, because the strength of the bonding between the electrode 104 having the plating 104a coated on its surface and the resin layer 109 is small, entire bonding strength between the core substrate 101 and the resin layer 109 is also reduced. As a result, the resin of the resin layer 109 filled between the core substrate 101 and the electronic component 106 may peel off when a small vibration is applied from the outside, or when the solder 108 is re-melted, made molten again and expanded with application of heat from the outside.

The other cause of the peeling-off resides in that, when water attached during a plating step is not sufficiently removed and remains at, e.g., the interface between the core substrate 101 and the resin layer 109 and the interface between the electronic component 106 and the resin layer 109, the water may be expanded to cause the peeling-off at those interfaces with application of heat from the outside. The problem of the residual water is more apt to occur when the core substrate 101 is made of resin than when the core substrate 101 is made of ceramic. The water attached during the plating step has to be sufficiently removed in order to prevent the water from remaining. This, however, requires heat treatment and raises a problem that a manufacturing process is complicated, or a problem that the core substrate 101, etc. may cause warping, contraction, distortion, etc. Further, the warping, the contraction, the distortion, etc. may give rise to a conduction failure or a short-circuit failure in the intra-core-substrate wiring of the core substrate 101.

As described above, the occurrence of the gaps or the peeling-off in the resin of the resin layer 109 filled between the core substrate 101 and the electronic component 106 raises the following problem. With application of heat under reflow soldering when the electronic components 106 and 107 are mounted to the other principal surface (i.e., the upper principal surface in FIG. 5) of the core substrate 101, or when the completed composite module 500 is mounted to another substrate, the re-melted and expanded solders 108 have nowhere to go and enter the gaps or the peeled-off portions, thus short-circuiting both the terminals 106a of the electronic component 106.

FIG. 7 illustrates the composite module 500 in which a re-melted and expanded solder 108′ has entered a peeled-off portion 113 formed between the electronic component 106 and the resin layer 109. It is to be noted that FIG. 5 and FIG. 7 are reversed in the up-and-down direction.

If the solder flash phenomenon causes short-circuiting between both the terminals 106a of the electronic component 106 through the solder 108′, the composite module 500 fails to normally function, thus resulting in a very serious problem.

Another problem is that the related-art composite module 500 requires a complicated manufacturing process and has low productivity. More specifically, in the composite module 500, the platings 104a and 105a are coated respectively on the electrodes 104 and 105, which are formed on both the principal surfaces of the core substrate 101, and the platings 111a are coated on the electrodes 111, which are formed on the surface of the resin layer 109. Even if the platings 104a and 105a are formed at the same time, the platings 111a have to be separately formed, and at least two plating steps are needed to manufacture the composite module 500. Accordingly, the manufacturing process is complicated and productivity is low.

### SUMMARY OF THE INVENTION

In view of the above, an electronic component incorporating board according to a preferred embodiment of the present invention includes a core substrate, electrodes located on each of one principal surface and the other principal surface of the core substrate, an electronic component mounted to the electrodes that are located on the one principal surface of the core substrate, and a resin layer located on the one principal surface of the core substrate and covering the electronic component, wherein surfaces of the electrodes located on the one principal surface of the core substrate are not plated.

Alternatively, an electronic component incorporating board according to another preferred embodiment of the present invention includes a core substrate, electrodes located on each of one principal surface and the other principal surface of the core substrate, an electronic component mounted to the electrodes that are located on the one principal surface of the core substrate, and a resin layer located on the one principal surface of the core substrate and covering the electronic component, wherein the electrodes located on the one principal surface of the core substrate are preferably formed by printing a conductive paste and firing the conductive paste, those electrodes being in direct contact with the resin layer and with a bonding material used to mount the electronic component.

Preferably, electrodes are located on a surface of the resin layer, and surfaces of those electrodes and surfaces of the electrodes located on the other principal surface of the core substrate are plated.

A composite module according to a preferred embodiment of the present invention is preferably constituted by mounting one or more additional electronic components to the above-described electronic component incorporating board of a preferred embodiment of the present invention.

Since the electronic component incorporating board according to a preferred embodiment of the present invention has the above-described structure, a possibility of causing gaps or peeling-off in resin of the resin layer between the electronic component and the core substrate is significantly reduced and very low. Thus, a possibility of causing the solder flash phenomenon is very low even with application of heat during reflow soldering, for example, when the electronic component is mounted to the electronic component incorporating board, or when the electronic component incorporating board or the composite module using the electronic component incorporating board is mounted to another substrate.

According to a preferred embodiment of the present invention, first, since the electrodes to which terminals of the electronic component are bonded are not plated, the spacing between the core substrate and the electronic component can be increased. As a result, the resin of the resin layer can be sufficiently filled between the core substrate and the electronic component, and a possibility of causing gaps in the resin filled between the core substrate and the electronic component is significantly reduced and very low.

That point will be described in detail below with reference to FIGS. 8A and 8B. FIG. 8A is a sectional view representing a state where terminal electrodes of the electronic component are bonded to electrodes of which surfaces are not plated as in a preferred embodiment of the present invention. On the other hand, FIG. 8B is a sectional view illustrating the related-art composite module 500 again for comparison and representing a state where terminal electrodes of the electronic component are bonded to electrodes of which surfaces are plated.

As illustrated in FIG. 8A, when terminals 206a of an electronic component 206 are bonded, using solders 208, to electrodes 204 of which surfaces are not plated, the solders 208 do not spread over the electrodes 204 due to less wetting, and they stagnate on the electrodes 204 near the terminals 206a. The excessively accumulated solders 208 enter between the terminals 206a and the electrodes 204, thereby bonding the terminals 206a to the electrodes 204 in a state where the terminals 206a are raised. As a result, a spacing G1 between the electronic component 206 and the core substrate 201 is sufficiently increased to such an extent that resin of a resin layer 209 can be filled between the electronic component 206 and the core substrate 201 without producing gaps.

In contrast, as illustrated in FIG. 8B, when terminals 106a of an electronic component 106 are bonded, using solders 108, to electrodes 104 having platings 104a coated on their surfaces, the solders 108 spread over the platings 104a with good wetting, thereby bonding the terminals 106a to the electrodes 104 (platings 104a). Because each solder 108 spreads with good wetting, the solder 108 is not excessively accumulated and is present in a state of a thin layer between the terminal 106a and the electrode 104 (plating 104a). Accordingly, a spacing G2 between the electronic component 106 and the core substrate 101 is reduced.

Further, according to a preferred embodiment of the present invention, since the electrodes to which terminals of the electronic component are bonded are not plated, a possibility of causing the peeling-off later in the resin of the resin layer between the core substrate and the electronic component is significantly reduced and very low. This is primarily due to the reasons described below.

First, in the case of bonding the electrode including the not-plated surface and the resin layer to each other as in a preferred embodiment of the present invention, the bonding strength is, as described above, larger than that in the case of bonding the electrode having the plated surface and the resin layer to each other. Additionally, the bonding strength is increased because the solder does not spread due to less wetting over the electrode to which the terminal of the electronic component is bonded, and because an area of the bonding surface between the electrode and the resin layer is increased. As a result, the overall bonding strength between the core substrate and the resin layer is also increased, and a possibility of causing the peeling-off is significantly reduced and very low even with application of vibration and heat from the outside.

Further, in a preferred embodiment of the present invention, since a plating step is not required to be performed before forming the resin layer on the core substrate, water does not remain at the interface between the core substrate and the resin layer and the interface between the electronic component and the resin layer. Even with application of heat from the outside, therefore, it is possible to avoid such a phenomenon that the water is expanded to cause the peeling-off at those interfaces.

Moreover, according to a preferred embodiment of the present invention, even when the solder is re-melted with application of heat, the re-melted solder does not expand in a direction in which the mounted electronic component is peeled off from the core substrate. That point will be described below with reference to FIGS. 8A and 8B again.

As illustrated in FIG. 8A, when the terminals 206a of the electronic component 206 are bonded, using the solders 208, to the electrodes 204 of which surfaces are not plated, as described above, the solders 208 do not spread over the electrodes 204 due to less wetting, and they stagnate on the electrodes 204 near the terminals 206a. In other words, each solder 208 preferably has a vertically elongated shape along the terminal 206a. Consequently, even when the solder 208 is re-melted with application of heat to the completed electronic component incorporating board, the solder 208 expands primarily in a direction denoted by an arrow E1 in FIG. 8A, i.e., a direction parallel or substantially parallel to the core substrate 201, and it does not expand in a direction in which the electronic component 206 is peeled off from the core substrate 201. Hence, the possibility of causing the peeling-off of the resin of the resin layer 209 between the core substrate 201 and the electronic component 206 is significantly reduced and very low.

In contrast, as illustrated in FIG. 8B, when the terminals 106a of the electronic component 106 are bonded, using the solders 108, to the electrodes 104 having the platings 104a coated on their surfaces, the solders 108 spread over the platings 104a with good wetting. Consequently, when each solder 108 is re-melted with application of heat to the completed electronic component incorporating board, the solder 108 expands in a direction closer to the direction in which the electronic component 106 is peeled off from the core substrate 101, as denoted by an arrow E2 in FIG. 8B, than the direction denoted by the arrow E1 in FIG. 8A. As a result, there is a possibility of causing the peeling-off of the resin layer 109 between the electronic component 106 and the core substrate 101, or a possibility of increasing the peeling-off that has already generated.

According to a preferred embodiment of the present invention, as described above, since the spacing between the core substrate and the electronic component can be increased and the resin of the resin layer can be sufficiently filled between the core substrate and the electronic component, the possibility of causing gaps in the resin filled between the core substrate and the electronic component is significantly reduced and very low. The possibility of causing the peeling-off later in the resin of the resin layer between the core substrate and the electronic component is also significantly reduced and very low. Hence, the possibility of causing the solder flash phenomenon is significantly reduced and very low even with application of heat under reflow soldering, for example, when the electronic component is mounted to the electronic component incorporating board, or when the electronic component incorporating board or the composite module using the electronic component incorporating board is mounted to another substrate.

Further, according to a preferred embodiment of the present invention, even when platings are coated on not only surfaces of the electrodes located on the principal surface of the core substrate, on which the resin layer is not provided, but also on surfaces of the electrodes located on the surface of the resin layer, both the platings can be formed in one plating step. Therefore, a manufacturing process is simplified, thus resulting in higher productivity. Thus, two plating steps are not required in the manufacturing process unlike the related-art composite module 500.

While the advantageous effects obtained with the electronic component incorporating board of various preferred embodiments of the present invention have been described above, the composite module according to a preferred embodiment of the present invention, which is constituted by mounting one or more additional electronic components to the electronic component incorporating board of one of the various preferred embodiments of the present invention, can also provide similar advantageous effects.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a sectional view illustrating an electronic component incorporating board 100 according to a first preferred embodiment of the present invention.

FIG. 2 is a sectional view illustrating a composite module 200 according to a second preferred embodiment of the present invention.

FIG. 3 is a sectional view illustrating a composite module 300 according to a third preferred embodiment of the present invention.

FIG. 4 is a sectional view illustrating a composite module 400 according to a fourth preferred embodiment of the present invention.

FIG. 5 is a sectional view illustrating a related-art composite module 500.

FIGS. 6A and 6B are sectional views illustrating the related-art composite module 500 in which a failure (gap 112) has occurred, wherein FIG. 6B is a sectional view taken along a broken line X-X in FIG. 6A.

FIG. 7 is a sectional view illustrating the related-art composite module 500 in which a failure (short-circuiting between both the terminals 106a of the electronic component 106 with the solder 108′ having entered the peeled-off portion 113) has occurred.

FIG. 8A is a sectional view of an electronic component incorporating board and a composite module to explain advantageous effects of a preferred embodiment of the present invention, and FIG. 8B is a sectional view illustrating the related-art composite module 500 for comparison.

### DETAILED DESCRIPTION OF THE PREFERRED EMBODIMENTS

Preferred embodiments of the present invention will be described below with reference to the drawings.

### First Preferred Embodiment

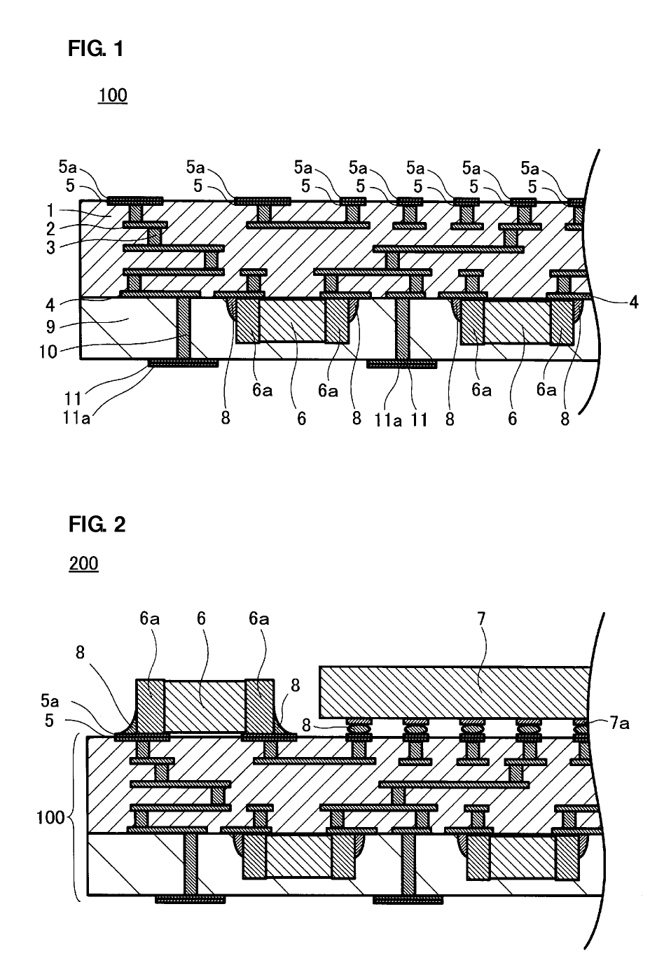

FIG. 1 illustrates an electronic component incorporating board 100 according to a first preferred embodiment of the present invention.

The electronic component incorporating board 100 includes a core substrate 1. The core substrate 1 is, e.g., a ceramic multilayered substrate, a resin multilayered substrate, or a printed substrate. Wiring patterns 2 and via holes 3 are provided inside the core substrate 1 to constitute the desired wiring within the core substrate. In this preferred embodiment, a multilayered substrate made of Low-Temperature Co-fired Ceramic (LTCC) is preferably used as the core substrate 1.

Electrodes 4 are located on one principal surface (lower principal surface in FIG. 1) of the core substrate 1, and electrodes 5 are located on the other principal surface (upper principal surface in FIG. 1).

For example, Ag or Cu is preferably used for the wiring patterns 2, the via holes 3, and the electrodes 4 and 5. Further, platings 5a preferably made of Ni/Au or Ni/Sn, for example, are formed on surfaces of the electrode 5 for improvement of solder wetting. On the other hand, platings are not coated on surfaces of the electrodes 4.

Further, electronic components 6, each including a pair of terminals (outer electrodes) 6a and 6a formed at both ends thereof, are mounted to the electrodes 4 using solders 8 as bonding materials. In this preferred embodiment, the electronic components 6 preferably are each a chip ceramic capacitor having device dimensions of about 0.6 mm length, about 0.3 mm width, and about 0.3 mm height, for example. The terminals 6a and 6a, each obtained by plating Sn on Ni with a thickness of about 10 μm, for example, are preferably formed at both ends of the capacitor. On the other hand, the electrodes 4 are each preferably made of Cu with dimensions of about 10 μm thickness, about 0.3 mm length, and about 0.3 mm width, for example. Because the electrode 4 is not plated, the spacing between the electronic component 6 and the core substrate 1 is increased in comparison with that in the related art. A value of the spacing preferably is about 30 μm to about 40 μm, for example, in this preferred embodiment. It is to be noted that the electronic components 6 mounted as described above in FIG. 1 are illustrated by way of example, and that electronic components of various types, structures and numbers may be mounted without being limited to the illustrated ones. Further, the bonding material is not limited to the solder 8, and it may be, e.g., a conductive adhesive.

Further, a resin layer 9 is formed on the principal surface of the core substrate 1 on the side where the electrodes 4 are formed (i.e., on the lower principal surface in FIG. 1) such that the resin layer 9 covers the electronic components 6. The resin layer 9 is preferably made of, e.g., a thermosetting epoxy resin, silicone resin, or cyanate resin, each containing an inorganic filler, such as Al₂O₃, SiO₂ or TiO₂. Via holes 10 connected to the electrodes 4 of the core substrate 1 are formed inside the resin layer 9, and electrodes 11 connected to the via holes 10 are formed on a surface of the resin layer 9. For example, Ag or Cu is also preferably used for the via holes 10 and the electrodes 11. Moreover, platings 11a made of Ni/Au or Ni/Sn, for example, are preferably formed on surfaces of the electrode 11 for improvement of solder wetting, for example.

The electronic component incorporating board 100 having the above-described structure, according to the first preferred embodiment of the present invention, is preferably manufactured according to the non-limiting example of a method of manufacturing described below.

First, a multilayered substrate made of Low-Temperature Co-fired Ceramic is formed as the core substrate 1.

In more detail, first, ceramic slurry is coated on a resin film made of, e.g., PET and is then dried, thereby obtaining a ceramic green sheet with a thickness of about 10 μm to about 200 μm. Ceramic powder to be contained in the ceramic slurry can be provided as, e.g., a mixture of BaO, SiO₂, Al₂O₃, B₂O₃, and CaO.

Next, through-holes of about 0.1 mm are formed in the green sheet with, e.g., a die or laser irradiation. A conductive paste is prepared by kneading metal particles that contain, e.g., Ag, Cu, Au or Ni as a main component, a thermosetting resin made of, e.g., epoxy, phenol or cyanate, and an organic solvent together. The conductive paste is filled in the through-holes and is then dried. The via holes 3 are thereby formed.

Next, the above-mentioned conductive paste is printed in the desired pattern on a predetermined front surface or rear surface of the green sheet with screen printing, for example, and is then dried. The wiring patterns 2 and the electrodes 4 and 5 are thereby formed.

Next, an appropriate number of green sheets are stacked one above another and press-bonded together at a temperature of about 40° C. to 100° C. under pressure of about 100 kgf/cm² to 2000 kgf/cm².

Next, an obtained laminate is fired at temperature of approximately 850° C. in an air atmosphere when the conductive paste is an Ag-based paste, and at temperature of approximately 950° C. in an N₂ atmosphere when the conductive paste is a Cu-based paste. As a result, the core substrate 1 is obtained which includes the wiring patterns 2 and the via holes 3 both formed inside the core substrate 1, and the electrodes 4 and 5 formed on the respective principal surfaces thereof.

Next, the electronic components 6 are mounted to the electrodes 4 of the core substrate 1. More specifically, a cream solder is previously coated on the surfaces of the electrodes 4, and the terminals 6a of each electronic component 6 are placed on the electrodes 4, respectively. By heating the cream solder to be re-melted and then cooling it to be re-solidified, the terminals 6a are bonded to the electrodes 4 with the solders 8. As described above, because the surface of each electrode 4 is not plated, the solder 8 does not spread over the electrode 4 due to less wetting, and the excessively accumulated solder 8 enters between the terminal 6a and the electrode 4, thereby bonding the terminal 6a to the electrode 4 in a state in which the terminal 6a is raised. As a result, the spacing between the core substrate 1 and the electronic component 6 is sufficiently increased. It is to be noted that, although the bonding between the terminal 6a and the electrode 4 is slightly weakened because the solder 8 does not spread due to less wetting, there is no problem in bonding strength because the electronic component 6 is covered with the resin layer 9 as described below.

Next, the resin layer 9 is formed on the core substrate 1 on which the electronic components 6 have been mounted. More specifically, a thermosetting resin sheet made of an epoxy resin, a phenol resin, or a cyanate resin, for example, which has been heated into a semi-molten state (B-stage state), is placed on the core substrate 1 and is caused to reach and contact with the periphery of each electronic component 6 by pressing the semi-molten resin in an atmosphere under pressure reduced to near vacuum. According to a preferred embodiment of the present invention, since the spacing between the core substrate 1 and the electronic component 6 is large, the resin forming the resin layer 9 is allowed to sufficiently enter between the core substrate 1 and the electronic component 6. Thus, gaps that are not filled with the resin are not produced, for example, right under the electronic component 6.

Next, holes are formed through the resin layer 9 to penetrate from its surface to the electrodes 4 with irradiation using a CO₂ laser. A desmear process is then performed by removing resin residues, which remain on, e.g., surfaces of the electrodes 4 exposed at bottom surfaces of the holes and on inner walls of the holes, with chemicals. The holes are then filled with the above-mentioned conductive paste or solder, whereby the via holes 10 are formed.

Next, a metal foil made of Cu or Ag, for example, is pasted over the entire surface of the resin layer 9.

Next, the core substrate 1, the resin layer 9, and the metal foil pasted to the resin layer 9 are integrated together by heating the entire core substrate 1 in a pressurized state and by hardening the resin of the resin layer 9. When the conductive paste is filled in the via holes 10, the conductive paste is also hardened at the same time. When the solder is filled in the via holes 10, the solder is subjected to reflow. In any case, the via holes 10 and the metal foil pasted to the resin layer 9 are bonded to each other.

Next, the electrodes 11 are formed by etching the metal foil, which has been pasted to the surface of the resin layer 9, into a desired pattern.

Finally, the platings 5a and 11a made of Ni/Au or Ni/Sn, for example, are coated respectively on the surfaces of the electrodes 5, which have been formed on the other principal surface (upper principal surface in FIG. 1) of the core substrate 1, and the surfaces of the electrodes 11, which have been formed on the surface of the resin layer 9. A plating process is performed by, e.g., electroless plating. The electronic component incorporating board 100 is thus completed.

Examples of the structure and the manufacturing method of the electronic component incorporating board 100 according to the first preferred embodiment of the present invention have been described above. It is, however, to be noted that the present invention can be variously modified in conformity with the gist of the present invention without being limited to the above-described matters, features, steps or characteristics.

For example, while the multilayered substrate made of Low-Temperature Co-fired Ceramic is preferably used as the core substrate 1 in the electronic component incorporating board 100, a resin multilayered substrate or a printed substrate may be used instead. The core substrate 1 is not always required to have multiple layers. The core substrate 1 may be made of a single layer provided that the necessary wiring can be formed in the core substrate 1.

Further, while the chip ceramic capacitor is used as the electronic component 6 incorporated in the resin layer 9, the electronic component to be incorporated is not limited to the chip ceramic capacitor, and it may be another chip type of electronic component or an electronic component, e.g., IC or SAW, including many terminals on its bottom surface.

Still further, while the resin layer 9 is formed by laminating the resin sheet, which has been heated into the semi-molten state (B-stage state), on the core substrate 1, the resin layer 9 may be formed by dripping a liquid resin instead of using the resin sheet.

### Second Preferred Embodiment

FIG. 2 illustrates a composite module 200 according to a second preferred embodiment of the present invention.

The composite module 200 is constituted by mounting a chip-type electronic component 6, e.g., a capacitor, a resistor, or a coil, and another electronic component 7, e.g., an IC or SAW device, on the principal surface (upper principal surface in FIG. 2) of the electronic component incorporating board 100 according to the above-described first preferred embodiment. More specifically, terminals 6a and 6a located at both ends of the electronic component 6 and terminals 7a located on a bottom surface of the electronic component 7 are bonded, using solders 8, to the electrodes 5 that are located on the principal surface of the electronic component incorporating board 100 and that include the platings 5a coated on their surfaces.

In the composite module 200, a desired electronic circuit with higher function can be constituted by adding the other electronic components 6 and 7.

Because the plating 5a is coated on the surface of each electrode 5 that is located on the surface of the electronic component incorporating board 100, the solder 8 spreads over the plating 5a with good wetting, thereby firmly bonding the terminal 6a to the electrode 5 (plating 5a). The spreading of the solder 8 with good wetting prevents the solder 8 from coming into an excessively accumulated state. Thus, the spacing between the electronic component 6 and the electronic component incorporating board 100 is small. For example, the plating 5a made of Ni having a thickness of about 4 μm and Au having a thickness of about 0.1 μm is preferably coated on the surface of the electrode 5 made of Cu and having a thickness of about 10 μm, a length of about 0.3 mm, and a width of about 0.3 mm, and the chip-type electronic component 6 constituted by a device having a length of about 0.6 mm, a width of about 0.3 mm, and a height of about 0.3 mm and including, at both ends thereof, the terminals 6a and 6a each obtained by plating Sn on Ni with a thickness of about 10 μm is mounted to the electrode 5. In that case, the spacing between the electronic component 6 and the electronic component incorporating board 100 is as small as about 20 μm. However, since resin is not filled into that spacing, there is no significant problem.

### Third Preferred Embodiment

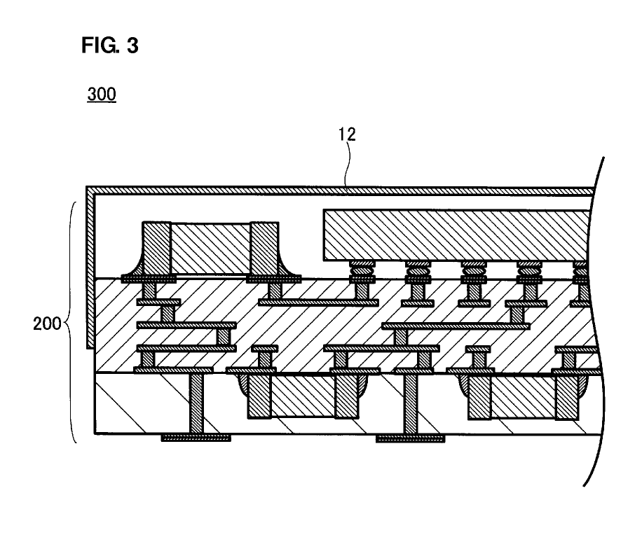

FIG. 3 illustrates a composite module 300 according to a third preferred embodiment of the present invention.

The composite module 300 has a structure in which an upper surface of the composite module 200 according to the above-described second preferred embodiment is covered with a metal case 12.

The metal case 12 can serve to shield the composite module 300 and to suppress not only the influence from the outside, but also the influence inversely to the outside. Further, a flat upper surface of the metal case 12 can be utilized as a suction surface for a mounter device when the composite module 300 is mounted to another substrate, for example.

### Fourth Preferred Embodiment

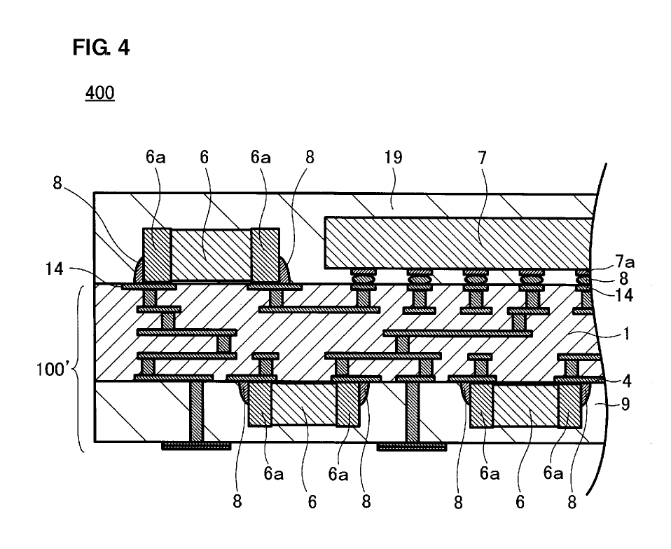

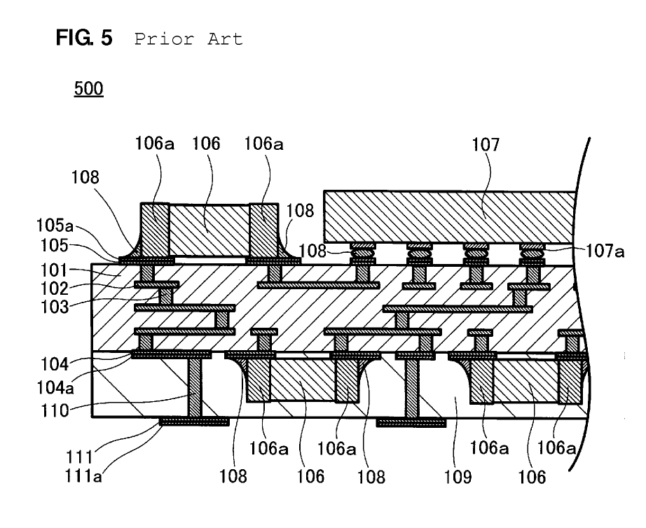

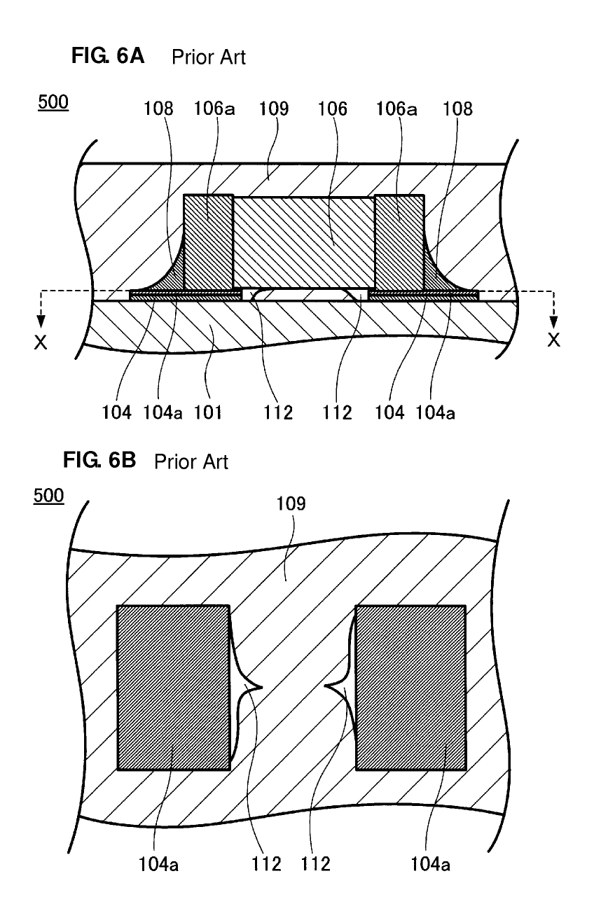

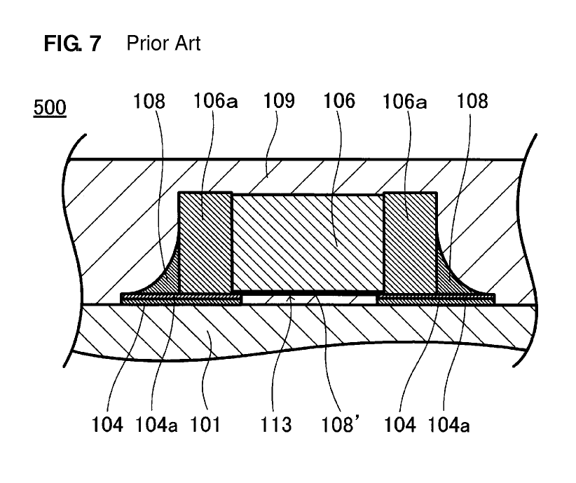

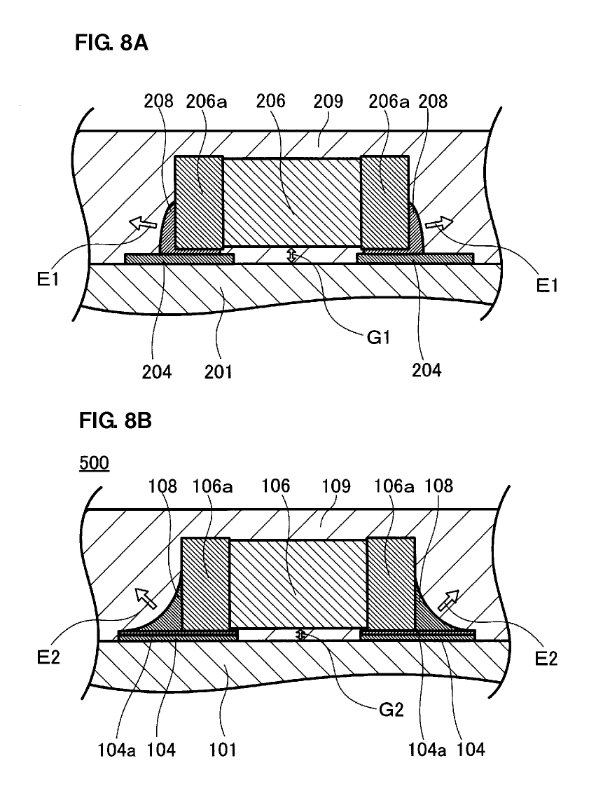

FIG. 4 illustrates a composite module 400 according to a fourth preferred embodiment of the present invention.

The composite module 400 preferably includes an electronic component incorporating board 100′ that is obtained by slightly modifying the electronic component incorporating board 100 according to the above-described first preferred embodiment. More specifically, in the electronic component incorporating board 100 (see FIG. 1), the electrodes 5 including the platings 5a coated on their surfaces are located on the other principal surface (upper principal surface in FIG. 1) of the core substrate 1. On the other hand, in the electronic component incorporating board 100′ (see FIG. 4), electrodes 14 having not-plated surfaces are formed on the other principal surface (upper principal surface in FIG. 4) of the core substrate 1.

Furthermore, in the composite module 400, after mounting the electronic components 6 and 7 to the electrodes 14, a resin layer 19 is located on the other principal surface of the core substrate 1. Thus, in the composite module 400, the resin layer 9 is located on the one principal surface of the core substrate 1, and the resin layer 19 is further located on the other principal surface of the core substrate 1.

In the composite module 400, because the surface of each electrode 14 is not plated, the solder 8 does not spread due to less wetting and the excessively accumulated solder 8 enters between the terminal 6a and the electrode 14, thereby bonding the terminal 6a to the electrode 14 in a state where the terminal 6a is raised. As a result, the spacing between the core substrate 1 and the electronic component 6 is large and the resin forming the resin layer 19 is allowed to sufficiently enter between the core substrate 1 and the electronic component 6. Hence gaps unfilled with the resin are not produced, for example, right under the electronic component 6.

The composite module 400 can be manufactured by adding several steps to the steps of manufacturing the electronic component incorporating board 100 according to the above-described first preferred embodiment. In more detail, a step of mounting the electronic components 6 and 7 to the electrodes 14 can be added before or after a step of mounting the electronic components 6 to the electrodes 4, or after forming the resin layer 9. Further, a step of laminating the resin layer 19 on the other principal surface of the core substrate 1 can be added before or after a step of laminating the resin layer 9 on the one principal surface of the core substrate 1.

In the composite module 400 according to the fourth preferred embodiment, although the resin layers 9 and 19 are provided respectively on both the principal surfaces of the core substrate 1 and the electronic components 6 and 7 are incorporated in the resin layers 9 and 19, a possibility of causing the solder flash phenomenon is low even with application of heat under reflow soldering when the composite module 400 is mounted to another substrate.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electronic component incorporating board comprising:
a core substrate;
electrodes located on each of a first principal surface and a second principal surface of the core substrate;
an electronic component mounted to the electrodes that are located on the first principal surface of the core substrate; and
a resin layer located on the first principal surface of the core substrate and covering the electronic component; wherein
surfaces of the electrodes located on the first principal surface of the core substrate are not plated.

2. The electronic component incorporating board according to claim 1, further comprising electrodes located on a surface of the resin layer and electrodes located on the second principal surface of the core substrate, wherein surfaces of the electrodes located on the surface of the resin layer and surfaces of the electrodes located on the second principal surface of the core substrate are plated.

3. The electronic component incorporating board according to claim 1, wherein the core substrate includes a plurality of layers defining a ceramic multilayered substrate or a resin multilayered substrate, and includes wiring patterns located between the plurality of layers and via holes extending respectively through the plurality of layers.

4. An electronic component incorporating board comprising:
a core substrate;
electrodes located on each of a first principal surface and a second principal surface of the core substrate;
an electronic component mounted to the electrodes that are located on the first principal surface of the core substrate; and
a resin layer located on the first principal surface of the core substrate and covering the electronic component; wherein
the electrodes located on the first principal surface of the core substrate are made of a printed and fired conductive paste;
the electrodes are in direct contact with the resin layer and with a bonding material used to mount the electronic component.

5. The electronic component incorporating board according to claim 4, further comprising electrodes located on a surface of the resin layer and electrodes located on the second principal surface of the core substrate, wherein surfaces of the electrodes located on the surface of the resin layer and surfaces of the electrodes located on the second principal surface of the core substrate are plated.

6. The electronic component incorporating board according to claim 4, wherein the core substrate includes a plurality of layers defining a ceramic multilayered substrate or a resin multilayered substrate, and includes wiring patterns located between the plurality of layers and via holes extending respectively through the plurality of layers.

7. A composite module comprising:
an electronic component incorporating board including:
a core substrate;
electrodes located on each of a first principal surface and a second principal surface of the core substrate;
an electronic component mounted to the electrodes that are located on the first principal surface of the core substrate; and
a resin layer located on the first principal surface of the core substrate and covering the electronic component; wherein
surfaces of the electrodes located on the first principal surface of the core substrate are not plated; and
at least one electronic component is mounted to the electrodes located on the second principal surface of the core substrate in the electronic component incorporating board.

8. The composite module according to claim 7, further comprising electrodes located on a surface of the resin layer and electrodes located on the second principal surface of the core substrate, wherein surfaces of the electrodes located on the surface of the resin layer and surfaces of the electrodes located on the second principal surface of the core substrate are plated.

9. The composite module according to claim 7, wherein the core substrate includes a plurality of layers defining a ceramic multilayered substrate or a resin multilayered substrate, and includes wiring patterns located between the plurality of layers and via holes extending respectively through the plurality of layers.

10. A composite module comprising:
an electronic component incorporating board including:
a core substrate;
electrodes located on each of a first principal surface and a second principal surface of the core substrate;
an electronic component mounted to the electrodes that are located on the first principal surface of the core substrate; and
a resin layer located on the first principal surface of the core substrate and covering the electronic component; wherein
the electrodes located on the first principal surface of the core substrate are made of a printed and fired conductive paste;
the electrodes are in direct contact with the resin layer and with a bonding material used to mount the electronic component; and
at least one electronic component is mounted to the electrodes located on the second principal surface of the core substrate in the electronic component incorporating board.

11. The composite module according to claim 10, further comprising electrodes located on a surface of the resin layer and electrodes located on the second principal surface of the core substrate, wherein surfaces of the electrodes located on the surface of the resin layer and surfaces of the electrodes located on the second principal surface of the core substrate are plated.

12. The composite module according to claim 10, wherein the core substrate includes a plurality of layers defining a ceramic multilayered substrate or a resin multilayered substrate, and includes wiring patterns located between the plurality of layers and via holes extending respectively through the plurality of layers.

13. A composite module comprising:
a core substrate including wiring therein;
electrodes located on each of a first principal surface and a second principal surface of the core substrate;
electronic components mounted respectively to the electrodes;
resin layers located respectively on the first principal surface and the second principal surface of the core substrate and covering the electronic components; and
electrodes located on a surface of at least one of the resin layers; wherein
surfaces of the electrodes located on each of the first principal surface and the second principal surface of the core substrate are not plated; and
surfaces of the electrodes located on the surface of the at least one of the resin layers are plated.

14. The composite module according to claim 13, further comprising electrodes located on the second principal surface of the core substrate, wherein surfaces of the electrodes located on the second principal surface of the core substrate are plated.

15. The composite module according to claim 13, wherein the core substrate includes a plurality of layers defining a ceramic multilayered substrate or a resin multilayered substrate, and the wiring includes wiring patterns located between the plurality of layers and via holes extending respectively through the plurality of layers.
